(19) United States
(12) Patent Application Publication
(10) Pub. No.: US 2022/0416501 A1
(43) Pub. Date: Dec. 29, 2022

(54) LASER LIGHT SOURCE

(71) Applicant: NICHIA CORPORATION, Anan-shi (JP)

(72) Inventors: Hidenori MATSUO, Hadano-shi (JP); Masatoshi NAKAGAKI, Komatsushima-shi (JP); Masaki OMORI, Toshima-ku (JP)

(73) Assignee: NICHIA CORPORATION, Anan-shi (JP)

(21) Appl. No.: 17/847,442

(22) Filed: Jun. 23, 2022

(30) Foreign Application Priority Data
Jun. 25, 2021 (JP) 2021-105699

(51) Int. Cl. H01S 5/02315; H01S 5/02325; H01S 5/02345

(52) U.S. Cl. CPC H01S 5/02315; H01S 5/02325; H01S 5/02345

(57) ABSTRACT

A laser light source includes: a submount having an upper surface; a semiconductor laser element located on the upper surface of the submount and having an end surface from which a laser beam is emitted; a lens facing the end surface of the semiconductor laser element; and a support member located on the upper surface of the submount and supporting the lens. The lens includes a collimating portion configured to collimate the laser beam emitted from the semiconductor laser element. The support member includes: a first portion and a second portion arranged at a lateral side of the submount; and a third portion that connects the first portion and the second portion and overlaps a portion of the semiconductor laser element in a plan view. The lens is supported by the first portion and the second portion via a bonding member.

### CROSS REFERENCE TO RELATED APPLICATION

This application claims priority to Japanese Patent Application No. 2021-105699, filed on Jun. 25, 2021, the entire contents of which are hereby incorporated by reference.

### BACKGROUND

The present disclosure relates to a laser light source.

Laser light sources including semiconductor laser elements are used in various applications such as machining, projectors and lighting appliances. A typical example of such a laser light source includes a semiconductor laser element, a submount that supports the semiconductor laser element, and a collimate lens that reduces the spread angle of light emitted from the semiconductor laser element (see, e.g., Japanese Patent Publication No. 2000-98190). When a semiconductor light-emitting element, a submount and a collimate lens are housed in a package, the laser light can be collimated at an appropriate degree of spread by a small-sized lens.

### SUMMARY

A laser light source is desired in which a bonding member for bonding the lens is disposed away from the light-incident surface of the lens.

According to one embodiment of the present disclosure, a laser light source includes: a submount having an upper surface; a semiconductor laser element provided on the upper surface of the submount and having an end surface from which a laser beam is emitted; a lens facing the end surface of the semiconductor laser element; and a support member provided on the upper surface of the submount and supporting the lens. The lens includes a collimating portion that collimates the laser beam emitted from the semiconductor laser element. The support member includes a first portion and a second portion arranged at a lateral side of the submount, and a third portion that connects together the first portion and the second portion and overlaps with a portion of the semiconductor laser element, as viewed in a plan view. The lens is supported by the first portion and the second portion of the support member with a bonding member interposed therebetween.

According to another embodiment of the present disclosure, a laser light source includes: a submount having an upper surface; a semiconductor laser element provided on the upper surface of the submount and having an end surface from which a laser beam is emitted; a lens facing the end surface of the semiconductor laser element; and a support member provided on the upper surface of the submount and supporting the lens. The lens includes: a collimating portion that faces the end surface of the semiconductor laser element and collimates the laser beam emitted from the semiconductor laser element; and an extension that extends from the collimating portion in a direction that is parallel to the end surface of the semiconductor laser element. The lens is supported with a bonding member disposed at least between the extension and the support member.

According to certain embodiments of the present disclosure, it is possible to provide a laser light source in which a bonding member for bonding the lens is disposed away from the light-incident surface of the lens.

### BRIEF DESCRIPTION OF THE DRAWINGS

FIG. 1A is an exploded perspective view schematically showing a configuration of a laser light source according to Embodiment 1 illustrative of the present disclosure.

FIG. 1B is a view schematically showing a planar configuration of the inside of the laser light source of FIG. 1A.

FIG. 2A is an exploded perspective view showing a more detailed configuration of the laser light source of FIG. 1A, where the package, lead terminals and wires are omitted.

FIG. 2B is a plan view schematically showing the laser light source of FIG. 2A.

FIG. 2C is a side view schematically showing the laser light source of FIG. 2A.

FIG. 2D is a back view schematically showing the laser light source of FIG. 2A.

FIG. 2E is a front view schematically showing the laser light source of FIG. 2A.

FIG. 3A is a view illustrating a method for bonding together the support member and the lens according to Embodiment 1.

FIG. 3B is a view illustrating the method for bonding together the support member and the lens according to Embodiment 1.

FIG. 4A is an exploded perspective view schematically showing a configuration of a laser light source according to Embodiment 2 illustrative of the present disclosure.

FIG. 4B is a plan view schematically showing the laser light source of FIG. 4A.

FIG. 4C is a side view schematically showing the laser light source of FIG. 4A.

FIG. 4D is a back view schematically showing the laser light source of FIG. 4A.

FIG. 4E is a front view schematically showing the laser light source of FIG. 4A.

FIG. 5A is a view illustrating a method for bonding together the support member and the lens according to Embodiment 2.

FIG. 5B is a view illustrating the method for bonding together the support member and the lens according to Embodiment 2.

### DETAILED DESCRIPTION

Hereinafter, with reference to the drawings, laser light sources according to certain embodiments of the present disclosure will be described in detail. The same reference signs in a plurality of drawings denote the same or similar parts.

The description below is intended to give a concrete form to the technical ideas of the present invention, but the scope of the present invention is not intended to be limited thereto. The size, material, shape, relative arrangement, etc., of the components are intended as examples, and the scope of the present invention is not intended to be limited thereto. The size, arrangement relationship, etc., of the members shown in each drawing may be exaggerated in order to facilitate understanding.

Where there is more than one of the same component, they may be prefixed with “first” and “second” in order to distinguish them from one another in the present specification or the claims. Where the manner in which the distinction is made in the present specification is different from that in the claims, the same prefix may not refer to the same member in the present specification and in the claims. The figures schematically show the X axis, the Y axis and the Z axis, orthogonal to each other, for reference. In the present specification, the direction of the arrow of the X axis will be referred to as the +X direction and the opposite direction as the −X direction. Where the ±X directions are not distinguished from each other, the direction will be referred to simply as the X direction. This similarly applies to the Y axis and the Z axis. In the present specification or in the claims, the +Y direction will be also denoted as “upward”, the −Y direction as “downward”, the +Z direction as “forward” and the −Z direction as “rearward” for the sake of illustration. As long as the relative directional/positional relationship is consistent throughout the drawings, it does not necessarily coincide with the arrangement on drawings other than those of the present disclosure, actual products and manufacturing apparatus, etc.

### Embodiment 1

A laser light source according to one embodiment of the present disclosure includes: a submount having an upper surface; a semiconductor laser element provided on the upper surface of the submount and having an end surface from which a laser beam is emitted; a lens facing the end surface of the semiconductor laser element; and a support member provided on the upper surface of the submount and supporting the lens. The lens includes a collimating portion that collimates the laser beam emitted from the semiconductor laser element. The support member includes a first portion and a second portion arranged at a lateral side of the submount, and a third portion that connects together the first portion and the second portion and overlaps with a portion of the semiconductor laser element, as viewed in a plan view. The lens is supported by the first portion and the second portion of the support member with a bonding member interposed therebetween.

With a laser light source of the present disclosure configured as described above, the bonding member for bonding the lens can be disposed away from the light-incident surface of the lens.

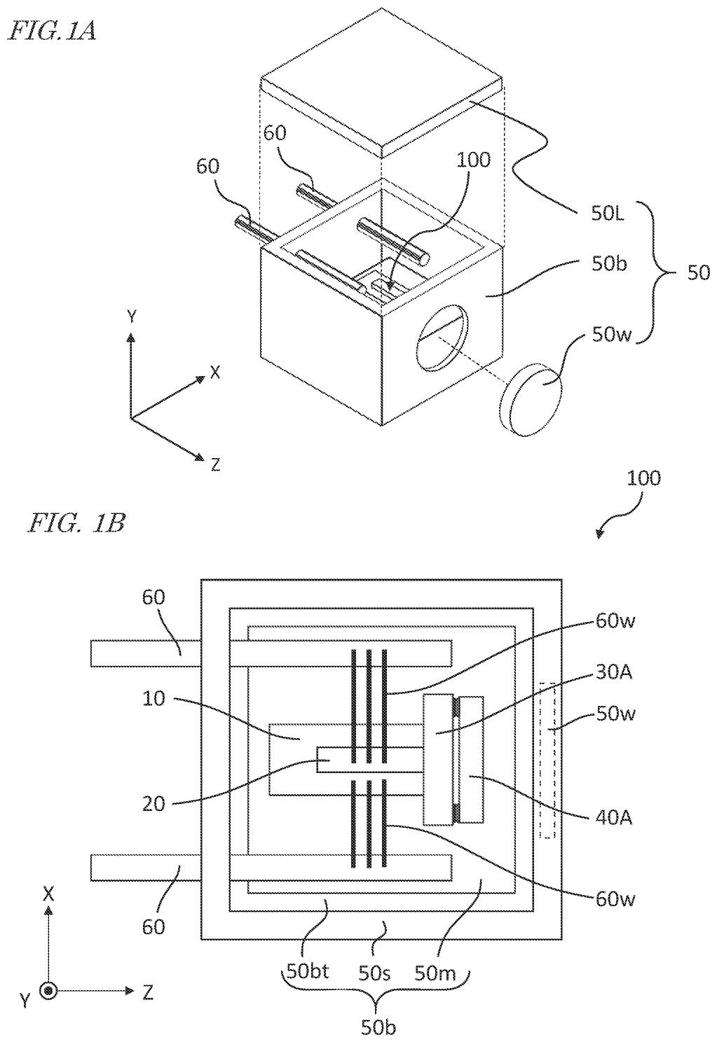

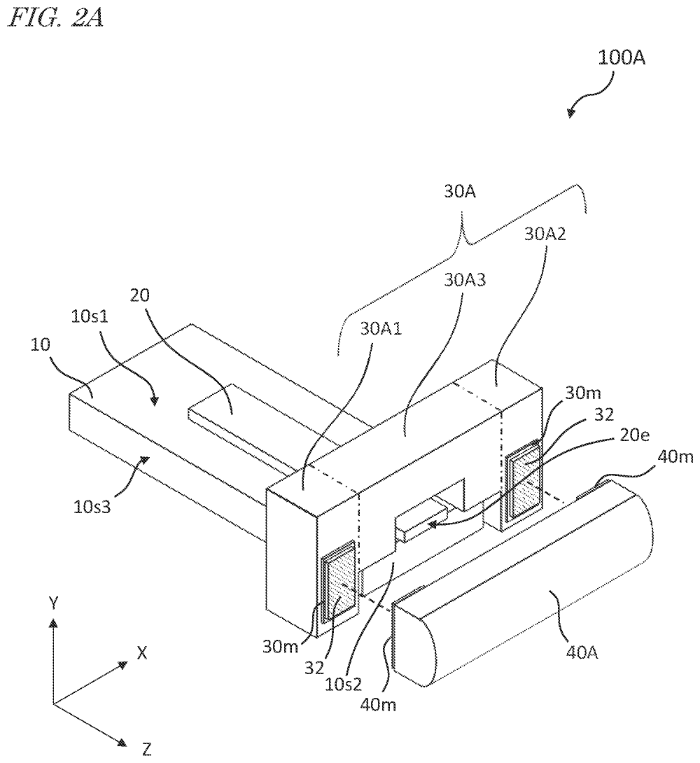

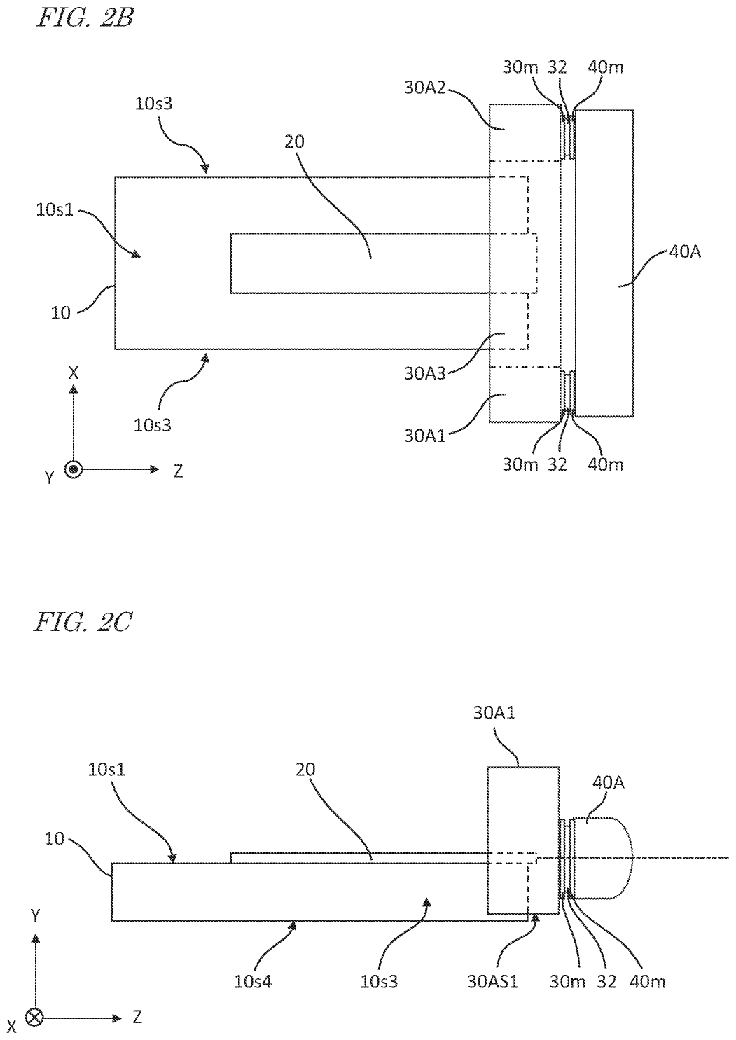

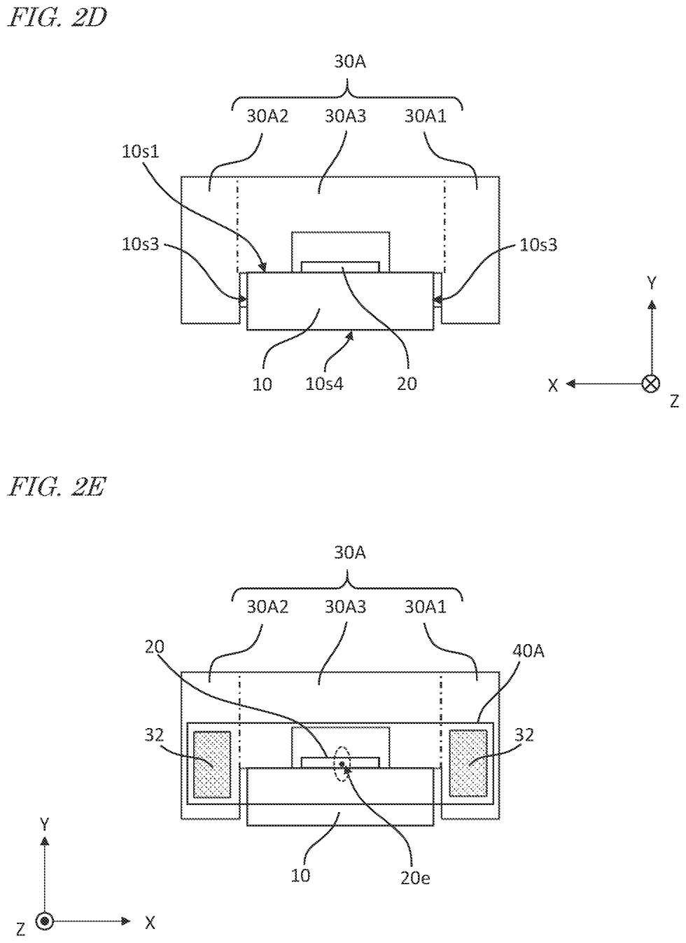

First, referring to FIG. 1A to FIG. 2E, an example of a laser light source according to Embodiment 1 of the present disclosure will be described.

FIG. 1A is an exploded perspective view schematically showing the configuration of a laser light source 100 according to Embodiment 1 illustrative of the present disclosure. The laser light source 100 shown in FIG. 1A includes, as a minimal configuration, a submount 10, a semiconductor laser element 20, a support member 30A and a lens 40A to be described below. It may also include a package 50 that houses those components, lead terminals 60 extending through the package 50, wires 60w that connect together the semiconductor laser element 20 and the lead terminals 60 and connect together the submount 10 and the lead terminals 60, thus forming the laser light source 100. The package 50 includes a lid 50L, a base 50b and a light-transmissive window 50w, for example. Light emitted from the semiconductor laser element 20 passes through the lens 40A, and is then extracted to the outside of the package 50 through the light-transmissive window 50w.

FIG. 1B is a view schematically showing a planar configuration of the inside of the laser light source 100 of FIG. 1A. In FIG. 1B, the lid 50L of the package 50 shown in FIG. 1A is omitted. The base 50b includes a bottom plate portion including an inner bottom surface 50bt, a stage 50m provided on the inner bottom surface 50bt, and a lateral wall 50s surrounding the stage 50m. The stage 50m supports the components housed in the package 50. The package 50 may hermetically seal these components. This can reduce optical dust collection. Optical dust collection is more likely to occur when the energy density is high. Therefore, when the peak wavelength of the laser beam emitted by the semiconductor laser element 20 is relatively short, e.g., 350 nm or more and 570 nm or less, optical dust collection can be reduced by hermetically sealing the semiconductor laser element 20 in the package 50. Note that the hermetic sealing of the package 50 may be done regardless of the wavelength of the laser beam emitted from the semiconductor laser element 20.

As shown in FIG. 1B, the lead terminals 60 are electrically connected to the semiconductor laser element 20 via the wires 60w and the submount 10. Current is supplied to the semiconductor laser element 20 through the lead terminals 60. The lead terminals 60 are electrically connected to an external circuit that adjusts the emission timing and output power of the laser beam emitted from the semiconductor laser element 20. In the example shown in FIG. 1B, one of the lead terminals 60 is electrically connected to a metal film formed on the upper surface of the semiconductor laser element 20 via three wires 60w, and the other one of the lead terminals 60 is electrically connected to a metal film formed on the upper surface of the submount 10 via three wires 60w. The number of wires 60w does not need to be three, but may be one or two, or may be four or more.

FIG. 2A is an exploded perspective view showing a more detailed configuration of the laser light source 100 of FIG. 1A, where the package 50, the lead terminals 60 and the wires 60w are omitted. The laser light source 100A shown in FIG. 2A includes the submount 10, the semiconductor laser element 20, the support member 30A and the lens 40A. In FIG. 2A, the support member 30A and the lens 40A are shown to be separated, but in reality they are bonded together. FIG. 2B, FIG. 2C, FIG. 2D and FIG. 2E are a plan view, a side view, a back view and a front view, respectively, schematically showing the laser light source 100A of FIG. 2A. In the front view shown in FIG. 2E, components that are located on the −Z direction side relative to the lens 40A are also shown by solid lines for the sake of illustration. The broken-line ellipse shown in FIG. 2E represents the light-incident surface of the lens 40A, on which the laser beam emitted from the semiconductor laser element 20 is incident. The black dot shown in FIG. 2E represents the center of gravity of the lens 40A.

The components will now be described below. Details such as the materials and sizes of the components will be described further below.

The submount 10 has an upper surface 10s1 that is parallel to the XZ plane as shown in FIG. 2A, and a front surface 10s2 that is located on the side close to the lens 40A. The submount 10 further has two lateral surfaces 10s3 located on opposite sides of each other as shown in FIG. 2B, and a lower surface 10s4 on the opposite side from the upper surface 10s1 as shown in FIG. 2C. The direction normal to the upper surface 10s1 is the +Y direction. In the present specification, viewing the upper surface 10s1 from the +Y direction to the −Y direction will be referred to as “viewing from above”.

The semiconductor laser element 20 is provided directly on the upper surface 10s1 of the submount 10, as shown in FIG. 2A. In the example shown in FIG. 2A, the semiconductor laser element 20 is a rectangular parallelepiped elongated in the Z direction. The semiconductor laser element 20 has an end surface 20e on the side close to the lens 40A among two end surfaces that intersect with the Z direction. The end surface 20e has a rectangular shape that extends along the X direction. The semiconductor laser element 20 emits a laser beam in the +Z direction from the end surface 20e. The laser beam spreads out at different speeds in the YZ plane and in the XZ plane as it travels in the +Z direction. The laser beam spreads out relatively fast in the YZ plane and spreads out relatively slowly in the XZ plane.

The semiconductor laser element 20 has a semiconductor stack structure including an n-type substrate, an n-type cladding layer, an active layer and a p-type cladding layer stacked in this order along the Y direction. The n-type and p-type may be reversed. Of the two end surfaces of the active layer intersecting with the Z direction, a laser beam is emitted from the forward end surface, i.e., the end surface 20e. In the example shown in FIG. 2A, the semiconductor laser element 20 is mounted in a so-called face-down configuration, where the active layer is closer to the submount 10 than the n-type substrate in the semiconductor stack structure. In face-down mounting, heat generated by the active layer while in operation can be efficiently transferred to the submount 10, the end surface 20e of the semiconductor laser element 20 can made to protrude more than the front surface 10s2 of the submount 10, as shown in FIG. 2A, so as to hinder the bonding member used for bonding together the submount 10 and the semiconductor laser element 20 from creeping up the end surface 20e. By allowing the end surface 20e of the semiconductor laser element 20 to be projected out more than the front surface 10s2 of the submount 10, it is also possible to hinder a portion of the laser beam emitted from the end surface 20e from being reflected by the submount 10. The semiconductor laser element 20 may be mounted in a so-called face-up configuration, where the n-type substrate is closer to the submount 10 than the active layer in the semiconductor stack structure.

The support member 30A is provided on the upper surface 10s1 of the submount 10, as shown in FIG. 2A. The support member 30A includes a first portion 30A1 and a second portion 30A2 that are arranged at a lateral side of the submount 10. The support member 30A also includes a third portion 30A3 that connects together the first portion 30A1 and the second portion 30A2 as shown in FIG. 2A and overlaps with a portion of the semiconductor laser element 20, as viewed in a plan view, as shown in FIG. 2B. Each of the first portion 30A1 and the second portion 30A2 has a surface that partially faces the lateral surfaces 10s3 of the submount 10, as shown in FIG. 2D. The first portion 30A1 and the second portion 30A2 support the lens 40A with the bonding member 32 interposed therebetween, as shown in FIG. 2A. The one-dot-chain lines shown in FIG. 2A, FIG. 2B, FIG. 2D and FIG. 2E represent the boundary between the first portion 30A1 and the third portion 30A3, and the boundary between the second portion 30A2 and the third portion 30A3. In the laser light source 100 according to Embodiment 1, the first portion 30A1, the second portion 30A2 and the third portion 30A3 are formed monolithically. This allows the mechanical strength of the support member 30A to be improved. The first portion 30A1, the second portion 30A2 and the third portion 30A3 of the support member 30A may be formed separately and then bonded together. The support member 30A has a symmetrical bridge shape as shown in FIG. 2D and FIG. 2E, and is arranged so as to straddle the semiconductor laser element 20 provided on the upper surface 10s1 of the submount 10. Therefore, the support member 30A does not interfere with the travel of the laser beam emitted from the semiconductor laser element 20. Because the bonding member 32 is not irradiated with the laser beam emitted from the semiconductor laser element 20 while in operation, the laser beam can be efficiently extracted to the outside. It is possible to prevent the beam pattern from being disturbed by the bonding member 32. Because the semiconductor laser element 20 is provided on the upper surface 10s1 of the submount 10, the heat generated from the semiconductor laser element 20 while in operation can be efficiently transmitted to the submount 10.

In face-down mounting of the semiconductor laser element 20, the bonding surfaces of the first portion 30A1 and the second portion 30A2 on which the bonding member 32 is disposed are located forward of the end surface 20e of the semiconductor laser element 20. The end surface 20e of the semiconductor laser element 20 is located forward of the front surface 10s2 of the submount 10. Because the bonding surfaces of the first portion 30A1 and the second portion 30A2 are located forward of the end surface 20e of the semiconductor laser element 20, it is possible to hinder the lens 40A from contacting the end surface 20e of the semiconductor laser element 20.

In face-up mounting of the semiconductor laser element 20, the end surface 20e of the semiconductor laser element 20 may be located on a plane including the front surface 10s2 of the submount 10 or may be located rearward of the front surface 10s2 of the submount 10. In this case, even if the bonding surfaces of the first portion 30A1 and the second portion 30A2 are located on the plane including the front surface 10s2 of the submount 10, the lens 40A can be hindered from contacting the end surface 20e of the semiconductor laser element 20.

As shown in FIGS. 2D and 2E, the third portion 30A3 is bonded to the upper surface 10s1 of the submount 10, while the first portion 30A1 and the second portion 30A2 are not bonded to the upper surface 10s1 of the submount 10. Because the third portion 30A3 connecting together the first portion 30A1 and the second portion 30A2 is bonded to the upper surface 10s1 of the submount 10, the first portion 30A1 and the second portion 30A2 can stably support the lens 40A. There is a gap between the first portion 30A1 and the submount 10 and between the second portion 30A2 and the submount 10. The gap allows the distance in the X-direction between the surfaces of the first portion 30A1 and the second portion 30A2 opposing each other to be larger than the size in the X-direction of the submount 10. As a result, it becomes easier to arrange the third portion 30A3 of the support member 30A on the upper surface 10s1 of the submount 10.

As shown in FIG. 2C, the first portion 30A1 has a bottom surface 30AS1. The bottom surface 30AS1 is located downward of the upper surface 10s1 of the submount 10 and upward of the lower surface 10s4 of the submount 10. This similarly applies to the bottom surface of the second portion 30A2. With such a configuration, when the laser light source 100A is mounted on other members, the first portion 30A1 and the second portion 30A2 do not interfere with the mounting. For example, when mounting on the package 50 as shown in FIG. 1A and FIG. 1B, the first portion 30A1 and the second portion 30A2 do not interfere with the mounting.

In the direction normal to the upper surface 10s1 of the submount 10, the size of the first portion 30A1 is larger than the size of the lens 40A. The bottom surface 30AS1 of the first portion 30A1 is located downward of a plane that includes the optical axis of the lens 40A (the dotted line of FIG. 2C) and is parallel to the bottom surface 30AS1. This similarly applies to the size and the bottom surface of the second portion 30A2 in the Y direction. As a result, the bonding surface between the first portion 30A1 and the lens 40A and the bonding surface between the second portion 30A2 and the lens 40A becomes wider, and the lens 40A can be stably supported by the first portion 30A1 and the second portion 30A2.

The lens 40A is arranged facing the end surface 20e of the semiconductor laser element 20, as shown in FIG. 2A. The lens 40A has a collimating portion that collimates the laser beam emitted from the semiconductor laser element 20. In the example shown in FIG. 2A, the lens 40A has a collimating portion that has a curvature in the YZ plane and extends uniformly along the X direction. This collimating portion collimates the fast axis direction of the laser beam emitted from the semiconductor laser element 20. Unlike the example shown in FIG. 2A, the lens 40A may have a collimating portion in a portion where the laser beam passes and a flat plate portion, for example, in other portions. In this specification, “to collimate” means not only to turn a laser beam into a parallel beam, but also to reduce the spread angle of a laser beam.

The lens 40A has its focal point on the optical axis rearward of the lens 40A. The light focused at the focal point and entering the lens 40A is collimated and emitted forward. The center of the end surface 20e of the semiconductor laser element 20 generally coincides with the focal point of the lens 40A. The optical axis of the lens 40A generally coincides with the optical axis of the laser beam emitted from the semiconductor laser element 20.

By supporting the lens 40A with the support member 30A, the distance between the end surface 20e of the semiconductor laser element 20 and the light-incident surface of the lens 40A facing the end surface 20e of the semiconductor laser element 20 can be shortened. This allows the lens 40A to reduce the spread of the laser beam emitted from the semiconductor laser element 20 before the laser beam spreads out significantly. As a result, it is possible to realize a compact laser light source 100A.

Depending on the application, the lens 40A may converge the laser beam emitted from the semiconductor laser element 20.

The first portion 30A1 and the second portion 30A2 are bonded to the lens 40A with the bonding member 32 interposed therebetween. Each of the first portion 30A1 and the second portion 30A2 may be provided with a first metal film 30m. Similarly, a second metal film 40m may be provided on the surface of the lens 40A that faces the first portion 30A1 and the second portion 30A2. In the Z direction, the first metal film 30m, the bonding member 32 and the second metal film 40m are arranged in this order, and are located between the first portion 30A1 and the second portion 30A2 and the lens 40A. The first metal film 30m and the second metal film 40m can improve the bonding strength between the support member 30A and the lens 40A with the bonding member 32 interposed therebetween.

As shown in FIG. 2E, the center of gravity (the black point) of the lens 40A is located between the two bonding surfaces on which the bonding member 32 is disposed in the X direction as viewed in a plan view from the optical axis direction of the laser beam emitted from the semiconductor laser element 20, i.e., as viewed from the +Z direction side. The center of gravity of the lens 40A is further located higher than the lower edge and lower than the upper edge of each bonding surface in the Y direction as viewed from the +Z direction side. By setting the center of gravity of the lens 40A at such a position, the lens 40A can be stably supported by the support member 30A.

Even if the thickness of the bonding member 32 decreases, the optical axis shift of the laser beam can be suppressed by aligning the laser emission point, the center of the lens and the center of the bonding member for the Y-axis direction.

Next, the materials and sizes of the components will be described.

[Submount 10] The submount 10 may be, for example, a rectangular parallelepiped. A part or the whole of submount 10 may be formed from at least one selected from the group consisting of AlN, SiC, alumina, CuW, Cu, a stack structure of Cu/AlN/Cu and a metal matrix compound (MMC), for example. An MMC includes diamond and at least one selected from the group consisting of Cu, Ag or Al, for example. Alternatively, a part or the whole of the submount 10 may be formed from other generally used materials. The thermal conductivity of a ceramic can be 10 [W/m·K] or more and 800 [W/m·K] or less, for example. With such a thermal conductivity, while in operation, the submount 10 can efficiently transfer the heat generated from the semiconductor laser element 20 to the package 50. The thermal expansion coefficient of the submount can be 2×10−6[1/K] or more and 2×10−5[1/K] or less, for example. Such a thermal expansion coefficient can hinder the submount 10 from being deformed by the heat applied when the semiconductor laser element 20 is bonded onto the submount 10 with a bonding member. The size of the submount 10 in the X direction is 1 mm or more and 3 mm or less, for example, the size in the Y direction is 0.1 mm or more and 0.5 mm or less, for example, and the size in the Z direction is 1 mm or more and 6 mm or less, for example.

The upper surface 10s1 and the lower surface 10s4 of the submount 10 may be formed with a metal film having a thickness of 0.5 pm or more and 10 μm or less, for example, by plating. The metal film formed on the upper surface 10s1 of the submount 10 is useful when bonding together the submount 10 and the semiconductor laser element 20 with a bonding member and when supplying power to the semiconductor laser element 20. The metal film formed on the lower surface 10s4 of the submount 10 is useful when bonding together the submount 10 and the stage 50m of the base 50b with a bonding member as shown in FIG. 1B.

[Semiconductor laser element 20] The semiconductor laser element 20 is capable of emitting a violet, blue, green or red laser beam in the visible region, or an infrared or ultraviolet laser beam in the invisible region. The emission peak wavelength for violet is preferably in the range of 350 nm or more and 420 nm or less, and more preferably in the range of 400 nm or more and 415 nm or less. The emission peak wavelength for blue is preferably in the range of greater than 420 nm and 495 nm or less, and more preferably in the range of 440 nm or more and 475 nm or less. The emission peak wavelength for green light is preferably in the range of greater than 495 nm and 570 nm or less, and more preferably in the range of 510 nm or more and 550 nm or less. Examples of laser diodes that emit a violet, blue and green laser beam include those containing a nitride semiconductor material. For example, GaN, InGaN and AlGaN can be used as the nitride semiconductor material. The emission peak wavelength for red light is preferably in the range of 605 nm or more and 750 nm or less, and more preferably in the range of 610 nm or more and 700 nm or less. Examples of laser diodes that emit a red laser beam include those containing InAlGaP-based, GaInP-based, GaAs-based and AlGaAs-based semiconductor materials, for example.

The size of the semiconductor laser element 20 in the X direction may be 50 μm or more and 500 μm or less, for example, the size in the Y direction may be 20 μm or more and 150 μm or less, for example, and the size in the Z direction may be 50 μm or more and 4 mm or less, for example. In face-down mounting, the distance in the Z direction between the end surface 20e of the semiconductor laser element 20 and the front surface 10s2 of the submount 10 may be 2 μm or more and 50 μm or less, for example.

Electrodes are provided on the upper surface and the lower surface of the semiconductor laser element 20. In the semiconductor stack structure of the semiconductor laser element 20 described above, the electrode electrically connected to the p-type cladding layer is referred to as the “p-side electrode” and the electrode electrically connected to the n-type substrate is referred to as the “n-side electrode”. By applying a voltage to the p-side electrode and the n-side electrode so as to allow a current to flow at a threshold value or more, the semiconductor laser element 20 emits a laser beam from the end surface 20e. The laser beam has a spread and forms an elliptical far-field pattern (hereinafter referred to as “FFP”.) in a plane parallel to the end surface 20e. FFP is the shape or intensity distribution of the emitted light at a position away from the end surface 20e. In the light intensity distribution, light having an intensity 1/e² or more relative to the peak power of the light intensity at the center of the beam is defined as a primary part of light. Here, “e” is the base of the natural logarithm.

The shape of the FFP of the laser beam emitted from the semiconductor laser element 20 is an elliptical shape. Of the elliptical shape, the major axis is parallel to the stacking direction of the semiconductor stack structure, and the minor axis is parallel to the direction in which the end surface 20e extends. The direction in which the end surface 20e extends is defined as the horizontal direction of the FFP and the stacking direction as the vertical direction of the FFP.

Based on the optical intensity distribution of the FFP, the angle corresponding to the full width at half-maximum of the optical intensity distribution is defined as the spread angle of the laser beam emitted from the semiconductor laser element 20. The vertical axis and the horizontal axis of the FFP are referred to as the fast axis and the slow axis, respectively.

[Support Member 30A]

The support member 30A may be formed from at least one selected from the group consisting of AlN, SiC, CuW, alumina, glass and Si, for example. Alternatively, the support member 30A may be formed from an alloy such as Kovar, for example. Kovar is an alloy in which nickel and cobalt are added to iron, which is the main component. The support member 30A may also be formed from a ceramic such as zirconia. The size of the first portion 30A1 and the second portion 30A2 of the support member 30A in the X direction may be 0.05 mm or more and 1 mm or less, the size in the Y direction may be 0.5 mm or more and 3 mm or less, for example, and the size in the Z direction may be 0.2 mm or more and 1 mm or less, for example. The maximum size of the third portion 30A3 of the support member 30A in the X direction may be 0.6 mm or more and 3 mm or less, the maximum size in the Y direction may be 0.1 mm or more and 3 mm or less, for example, and the size in the Z direction may be between 0.2 mm or more and 1 mm or less, for example.

The first metal film 30m is formed on surfaces of the first portion 30A1 and the second portion 30A2 of the support member 30A that face the lens 40A by plating, vapor deposition, or the like, for example. The first metal film 30m may be provided as a single layer or as multiple layers, as long as a layer of Cr, Au, or the like, for example, is provided on the uppermost surface of the first metal film 30m. If the first metal film 30m is formed as multiple layers, a layer of Cr, Ti, Ni, or the like, may be provided as a base layer, and a layer of Pt, Pd, Rt, or the like, may be provided as an intermediate layer.

The thermal conductivity of the support member 30A is higher than the thermal conductivity of the lens 40A and less than or equal to the thermal conductivity of the submount 10. According to such a thermal conductivity relationship, the heat applied to the bonding member 32 is more likely to dissipate to the submount 10 through the support member 30A, thereby suppressing the deterioration of the lens 40A due to heat. Therefore, during the step of bonding the lens 40A to be described below to the support member 30A, the lens 40A can be bonded to the support member 30A with a good yield.

[Bonding Member 32]

The bonding member 32 may be formed from a material that can be sintered, for example. In a sintering process, particles or powder of a metal is heated and sintered at a temperature lower than the melting point of that metal, so that members are bonded together. The sintering temperature is lower than the melting point of the metal that composes the particles, and may be 120° C. or more and 300° C. or less, for example. The sintering temperature corresponds to the bonding temperature of the bonding member.

For example, the material that can be sintered may be a metal paste that contains particles of at least one metal selected from the group consisting of Ag particles, Cu particles, Au particles and particles of other noble metals, and an organic binder. Because a metal paste containing an organic binder is flexible, the position of the lens 40A can be fine-adjusted when bonding together the support member 30A and the lens 40A.

If there is no need to fine-adjust the position of the lens 40A, then the bonding member 32 may be formed from a material that can be soldered or brazed. In a soldering or brazing process, a solder material or a brazing material is melted by raising the temperature and solidified by lowering the temperature, so that members are bonded together. The melting temperature of a solder material may be 180° C. or more and 300° C. or less, for example. The melting temperature of a brazing material may be 500° C. or more and 900° C. or less, for example. The melting temperature of a solder material or a brazing material corresponds to the bonding temperature of the bonding member.

A bonding member that can be soldered may be at least one solder material selected from the group consisting of AuSn, SnCu, SnAg and SnAgCu, for example. A bonding member that can be brazed may be at least one brazing material selected from the group consisting of a gold brazing material, a tin brazing material and a silver brazing material.

The thickness of the bonding member 32 may be 1 μm or more and 30 μm or less, for example. This can increase the bonding strength. Also, bonding can be completed in a short time.

[Lens 40A] The lens 40A may be formed from at least one light-transmissive material selected from the group consisting of glass, quartz, synthetic quartz, sapphire and light-transmissive ceramic, for example. Alternatively, the lens 40A may be formed from other common lens materials. The second metal film 40m is formed on a surface of the lens 40A that faces the first portion 30A1 and the second portion 30A2 of the support member 30A by plating, vapor deposition, or the like, for example. The material of the second metal film 40m may be the same as the material of the first metal film 30m, for example.

The size of the lens 40A in the X-direction may be equal to the maximum size of the support member 30A in the X-direction, or it may be larger or smaller than the maximum size of the support member 30A in the X-direction, for example. However, the size of the lens 40A in the X-direction is greater than the distance in the X-direction between the surfaces of the first portion 30A1 and the second portion 30A2 of the support member 30A opposing each other. The maximum size of the lens 40A in the Y direction may be 0.2 mm or more and 3 mm or less, for example, and the maximum size in the Z direction may be 0.2 mm or more and 3 mm or less, for example.

[Package 50]

Of the base 50b included in the package 50, the bottom plate portion including the inner bottom surface 50bt may be formed from a metal including at least one selected from the group consisting of Cu, Al, Ag, Fe, Ni, Mo, Cu, W and CuMo, for example. Such a metal has a high thermal conductivity, and the bottom plate portion formed from such a metal can efficiently transfer heat generated from the semiconductor laser element 20 while in operation to the outside. Of the base 50b included in the package 50, the lateral wall 50s surrounds the submount 10, the semiconductor laser element 20, the support member 30A and the lens 40A. The lateral wall 50s may be formed from Kovar, for example.

The stage 50m provided on the inner bottom surface 50bt of the base 50b allows the height of the end surface 20e of the semiconductor laser element 20 and the height of the light-transmissive window 50w to be aligned. The stage 50m may be formed from the same material as the bottom plate portion including the inner bottom surface 50bt of the base 50b. Alternatively, the stage 50m may be a protruding portion of at least a portion of the inner bottom surface 50bt of the base 50b.

The lid 50L included in the package 50 may be formed from the same material as the base 50b or from a different material. The material of the light-transmissive window 50w included in the package 50 may be formed from at least one light-transmissive material selected from the group consisting of glass, quartz, synthetic quartz, sapphire and light-transmissive ceramic, for example. Alternatively, the light-transmissive window 50w may be formed from other common lens materials.

[Lead terminal 60] The lead terminals 60 may be formed from a conductive material such as an Fe—Ni alloy or a Cu alloy, for example. The wires 60w may be formed from at least one metal selected from the group consisting of Au, Ag, Cu and Al, for example.

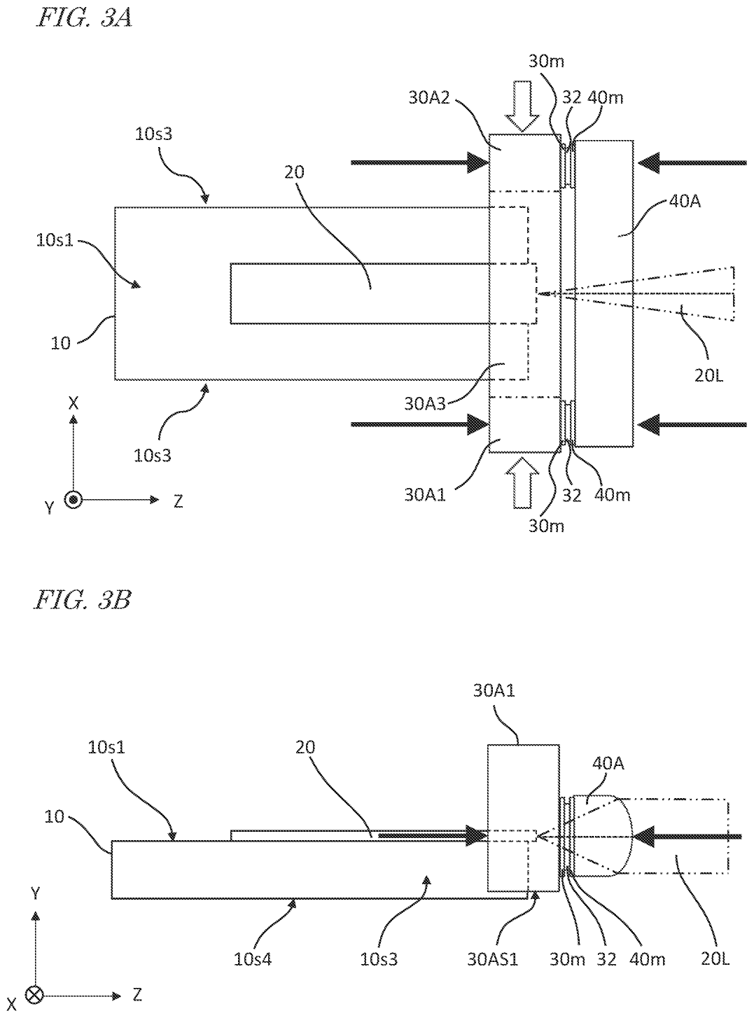

Next, referring to FIG. 3A and FIG. 3B, an example of a method for bonding the support member 30A and the lens 40A will be described. Before heating the bonding member 32, the support member 30A and the lens 40A are connected together with the bonding member 32 interposed therebetween. In this connection process, the surfaces of the first portion 30A1 and the lens 40A facing each other are generally parallel to each other. Similarly, the surfaces of the second portion 30A2 and the lens 40A facing each other are generally parallel to each other. The angle formed by these surfaces may be 0° or more and 10° or less, for example.

FIG. 3A and FIG. 3B are views illustrating a method for bonding together the support member 30A and the lens 40A in Embodiment 1. The area surrounded by the two-dot-chain line shown in FIG. 3A and FIG. 3B represent the primary part of a laser beam 20L emitted from the semiconductor laser element 20.

The white arrow shown in FIG. 3A schematically represents how a heating laser beam travels. As shown in FIG. 3A, the heating laser beam is emitted toward the lateral surfaces of the first portion 30A1 and the second portion 30A2. The power density of the heating laser beam may be 10 kW/cm² or more and 10000 kW/cm² or less, for example. The irradiation time of the laser beam may be 1 ms or more and 50 ms or less, for example. By irradiating and heating the first portion 30A1 and the second portion 30A2 with the laser beam, the heat can be transferred from the first portion 30A1 and the second portion 30A2 to the bonding member 32, so that the support member 30A and the lens 40A are bonded together. When the lower surface 10s4 of the submount 10 is in contact with the heat sink, the heat applied to the bonding member 32 is transferred from the first portion 30A1 and the second portion 30A2 to the heat sink through the third portion 30A3 and the submount 10 in this order.

There is no restriction on the wavelength of the heating laser beam, and ultraviolet light, blue light, green light, red light, infrared light, and the like, may be used. For example, a YAG laser light source can be used as the light source that emits the heating laser beam.

As shown in FIG. 2E, with the bonding member 32 provided on the first portion 30A1 and the second portion 30A2, the light-incident surface of the lens 40A (the broken-line ellipse), on which the laser beam 20L emitted from the semiconductor laser element 20 is incident, is farther away from the bonding member 32, as compared with a case where the bonding member 32 is provided on the third portion 30A3. Therefore, even if the bonding member 32 bumps while heating the bonding member 32, it is possible to reduce the possibility for a part of the bumping bonding member 32 to splash to the light-incident surface of the lens 40A. The shortest distance in the XY plane between the light-incident surface of the lens 40A and the bonding member 32 may be 0.2 mm or more and 1 mm or less, for example. If a part of the bumping bonding member 32 adheres to the light-incident surface of the lens 40A, a part of the laser beam emitted from the semiconductor laser element 20 hits the bonding member 32 while in operation. This may cause heat to accumulate in the bonding member, thereby burning the lens 40A. In contrast, with the laser light source 100A according to Embodiment 1, because the bonding member 32 is provided on the first portion 30A1 and the second portion 30A2, the position of the bonding member becomes farther away from the light-incident surface, on which the laser beam 20L emitted from the semiconductor laser element 20 is incident. Therefore, it is possible to reduce the adhesion of a part of the bumping bonding member 32 to the light-incident surface of the lens 40A, thereby suppressing the burning of the lens 40A. With the laser light source 100A according to Embodiment 1, the laser beam can be efficiently extracted to the outside. It is possible to suppress the beam pattern from being disturbed due to adhesion of a part of the bumping bonding member 32 to the light-incident surface of the lens 40A.

While heating the bonding member 32, the first portion 30A1 and the second portion 30A2 and the lens 40A are pressed against each other from opposite directions along one axis that is parallel to the optical axis of the laser beam (the dotted line), as represented by bold arrows shown in FIG. 3A and FIG. 3B. Because the first portion 30A1 and the second portion 30A2 and the lens 40A are pressed against each other along one axis, it is possible to prevent misalignment of the lens 40A while pressing. As shown in FIG. 2B and FIG. 2D, because the first portion 30A1 and the second portion 30A2 do not overlap with the submount 10 as viewed in a plan view and in a back view, the submount 10 does not interfere with the pressing. Moreover, when the bonding member 32 is formed from a metal paste, the lens 40A shifts in the direction of pressing by 0.1 μm or more and 3 μm or less, for example, because the bonding member 32 is flexible. The position of the lens 40A can be fine-adjusted by shifting it through the pressing while the laser beam 20L is emitted from the semiconductor laser element 20, so that the lens 40A can be installed at such a position that the laser beam 20L can be accurately collimated.

### Embodiment 2

A laser light source according to one embodiment of the present disclosure includes: a submount having an upper surface; a semiconductor laser element provided on the upper surface of the submount and having an end surface from which a laser beam is emitted; a lens facing the end surface of the semiconductor laser element; and a support member provided on the upper surface of the submount and supporting the lens. The lens includes: a collimating portion that faces the end surface of the semiconductor laser element and collimates the laser beam emitted from the semiconductor laser element; and an extension that extends from the collimating portion in a direction that is parallel to the end surface of the semiconductor laser element. The lens is supported with a bonding member disposed at least between the extension and the support member.

With a laser light source of the present disclosure configured as described above, the bonding member for bonding the lens can be disposed away from the light-incident surface of the lens.

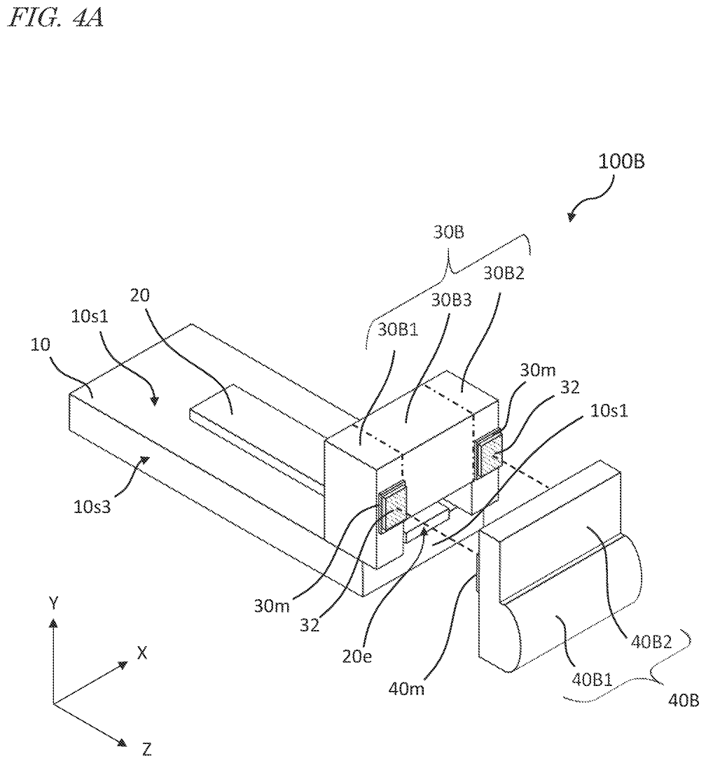

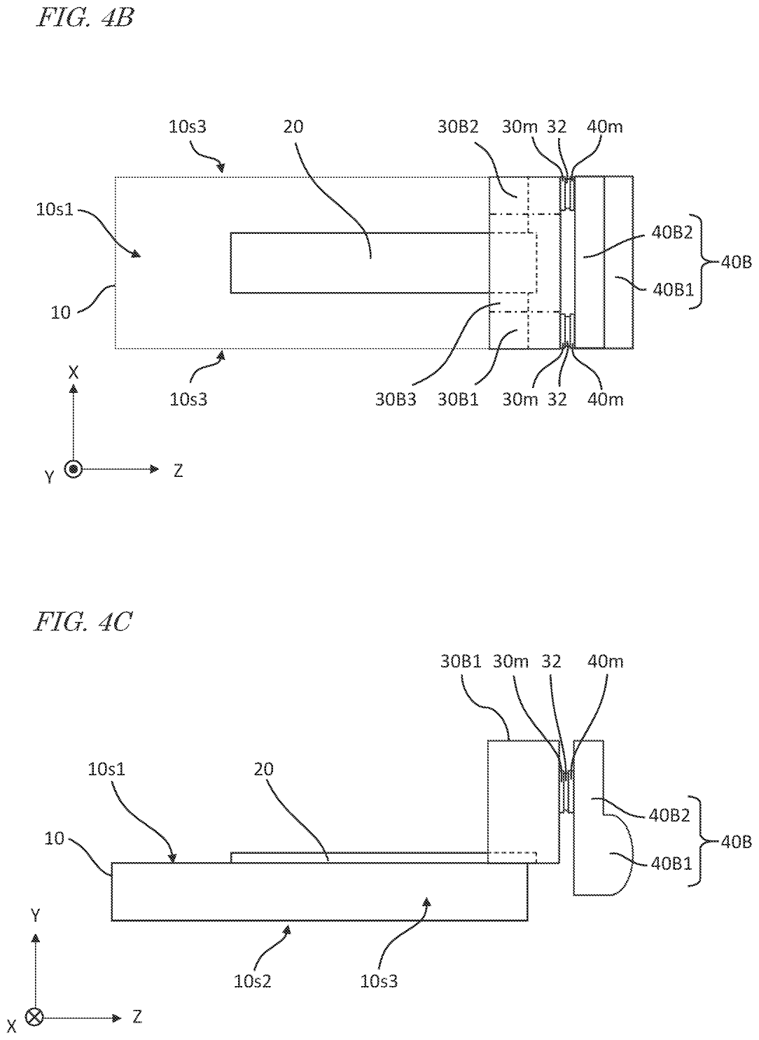

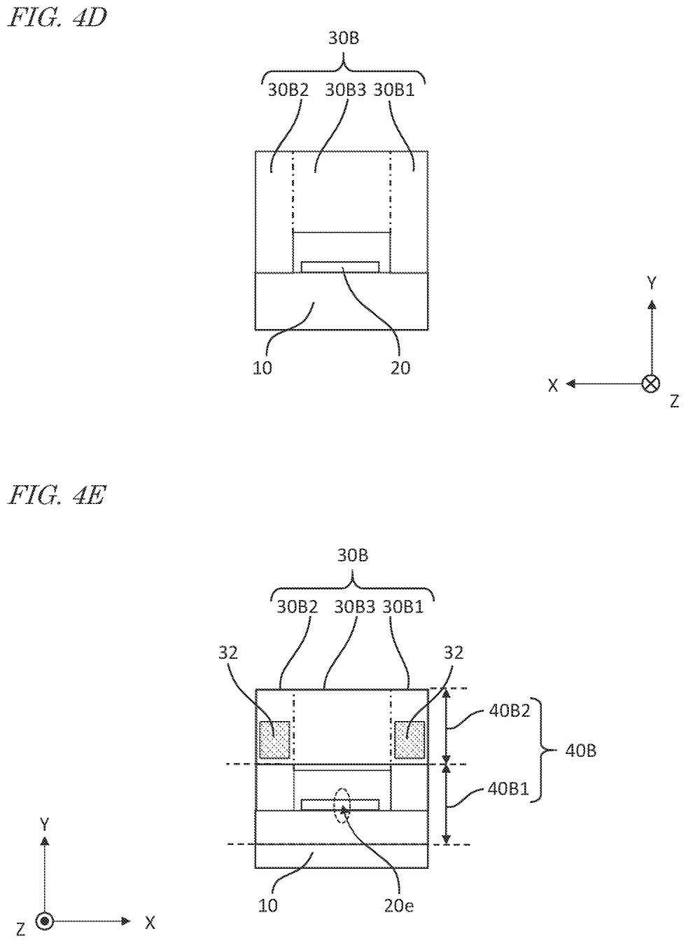

Now, referring to FIG. 4A to FIG. 4E, an example of the configuration of a laser light source according to Embodiment 2 of the present disclosure will be described, while focusing on how Embodiment 2 is different from Embodiment 1. Points that are similar to Embodiment 1 may be omitted from the description as appropriate. FIG. 4A is an exploded perspective view schematically showing the configuration of a laser light source 100B according to Embodiment 2 illustrative of the present disclosure. FIG. 4B, FIG. 4C, FIG. 4D and FIG. 4E are a plan view, a side view, a back view and a front view, respectively, schematically showing the laser light source 100B of FIG. 4A. In the front view shown in FIG. 4E, components that are located on the −Z direction side relative to the lens 40A are also shown by solid lines for the sake of illustration. The broken-line ellipse shown in FIG. 4E represents the light-incident surface of the lens 40A, on which the laser beam emitted from the semiconductor laser element 20 is incident.

The laser light source 100B shown in FIG. 4A is different from the laser light source 100A shown in FIG. 2A in terms of the shape of a support member 30B and the shape of a lens 40B. The support member 30B includes a first portion 30B1 and a second portion 30B2 that are arranged at a lateral side of the semiconductor laser element 20 as shown in FIG. 4A, and that are bonded to the upper surface 10s1 of the submount 10. The support member 30B also includes the third portion 30B3 that connects together the first portion 30B1 and the second portion 30B2 as shown in FIG. 4A and overlaps with a portion of the semiconductor laser element 20, as viewed in a plan view, as shown in FIG. 4B. The first portion 30B1 and the second portion 30B2 support the lens 40B with the bonding member 32 interposed therebetween. The one-dot-chain lines shown in FIG. 4A, FIG. 4B, FIG. 4D and FIG. 4E represent the boundary between the first portion 30B1 and the third portion 30B3, and the boundary between the second portion 30B2 and the third portion 30B3. In the laser light source 100B according to Embodiment 2, the first portion 30B1, the second portion 30B2 and the third portion 30B3 are formed monolithically. This allows the mechanical strength of the support member 30B to be improved. The first portion 30B1, the second portion 30B2 and the third portion 30B3 of the support member 30B may be formed separately and then bonded together. The support member 30B has a symmetrical bridge shape as shown in FIG. 4D and FIG. 4E, and is arranged so as to straddle the semiconductor laser element 20 provided on the upper surface 10s1 of the submount 10. Therefore, the support member 30B does not interfere with the travel of the laser beam emitted from the semiconductor laser element 20. The bonding member 32 is disposed only at positions such that the bonding member 32 is not irradiated with the laser beam emitted from the semiconductor laser element 20 when the semiconductor laser element 20 is driven. Therefore, it is possible to suppress the deterioration of the bonding member 32 due to irradiation by the laser beam. Because the semiconductor laser element 20 is provided on the upper surface 10s1 of the submount 10, the heat generated from the semiconductor laser element 20 while in operation can be efficiently transmitted to the submount 10.

The lens 40B is arranged facing the end surface 20e of the semiconductor laser element 20, as shown in FIG. 4A. Specifically, as shown in FIG. 4A, the lens 40B includes a collimating portion 40B1 that faces the end surface 20e of the semiconductor laser element 20 and collimates the laser beam emitted from the semiconductor laser element 20. The lens 40B further includes an extension 40B2 extending from the collimating portion 40B1 to be away from the end surface 20e in a direction parallel to the end surface 20e of the semiconductor laser element 20. The lens 40B is supported with the bonding member 32 disposed at least between the extension 40B2 and the support member 30B. Thus, the position of the bonding member can be brought away from the light-incident surface, where the laser beam emitted from the semiconductor laser element 20 is incident upon the lens 40B, and it is therefore possible to reduce the optical dust collection. For example, as shown in FIG. 4C and FIG. 4E, the bonding member 32 can be disposed only between the first portion 30B1 and the extension 40B2 and between the second portion 30B2 and the extension 40B2. Thus, the bonding member can be disposed farther away from the light-incident surface of the lens 40B. Therefore, it is possible to reduce the adhesion of a part of the bumping bonding member 32 to the light-incident surface of the lens 40B, thereby suppressing the burning of the lens 40B. With the laser light source 100B according to Embodiment 2, the laser beam can be efficiently extracted to the outside. It is possible to suppress the beam pattern from being disturbed due to adhesion of a part of the bumping bonding member 32 to the light-incident surface of the lens 40B.

The extension 40B2 extends in the direction normal to the upper surface 10s1 of the submount 10. Although the collimating portion 40B1 and the extension 40B2 are monolithically formed, the collimating portion 40B1 and the extension 40B2 may be formed separately and then bonded together. By forming the collimating portion 40B1 and the extension 40B2 monolithically, it is possible to improve the mechanical strength of the lens 40B.

The bonding member 32 may be disposed so as to include a central portion, but not an upper portion, of the first portion 30B1 and the second portion 30B2. “The bonding member 32 being disposed so as to include a central portion of the first portion 30B1 and the second portion 30B2” means that the bonding member 32 is disposed on the first portion 30B1 and the second portion 30B2 so as to include a position at a height that is half the size in the Y direction from the upper surface 10s1 of the submount. When the bonding member 32 is disposed in an upper portion of the first portion 30B1 and the second portion 30B2, the thickness of the bonding member 32 may decrease non-uniformly. This may cause the light-incident surface of the lens 40B, on which the laser beam emitted from the semiconductor laser element 20 is incident, to be tilted significantly relative to the end surface 20e of the semiconductor laser element 20. In contrast, when the bonding member 32 is placed in a central portion of the first portion 30B1 and the second portion 30B2, the thickness of the bonding member 32 is unlikely to decrease non-uniformly, and therefore can suppress the optical axis of the lens 40B from tilting in the Y-axis direction.

Because the distance between the end surface 20e of the semiconductor laser element 20 and the light-incident surface of the collimating portion 40B1 of the lens 40B that faces the end surface 20e is short, the spread of the laser beam emitted from the semiconductor laser element 20 can be reduced by the lens 40B before the laser beam broadly spreads out. As a result, it is possible to realize a compact laser light source 100B.

Next, the sizes of the support member 30B and the lens 40B will be described. The materials of the support member 30B and the lens 40B are the same as the materials of the support member 30A and the lens 40A of Embodiment 1.

The size of the first portion 30B1 and the second portion 30B2 of the support member 30B in the X direction may be 0.1 mm or more and 1 mm or less, the size in the Y direction may be 0.2 mm or more and 3 mm or less, for example, and the size in the Z direction may be 0.2 mm or more and 1 mm or less, for example. The size of the third portion 30B3 of the support member 30B in the X direction may be 0.2 mm or more and 3 mm or less, the size in the Y direction may be 0.2 mm or more and 3 mm or less, for example, and the size in the Z direction may be between 0.2 mm or more and 1 mm or less, for example.

The size of the lens 40B in the X-direction may be equal to the maximum size of the support member 30B in the X-direction, or it may be larger or smaller than the maximum size of the support member 30B in the X-direction, for example. However, the size of the lens 40B in the X-direction is greater than the distance in the X-direction between the surfaces of the first portion 30B1 and the second portion 30B2 of the support member 30B opposing each other.

The maximum size of the collimating portion 40B1 of the lens 40B in the Y direction may be 0.2 mm or more and 1 mm or less, for example, and the maximum size in the Z direction may be 0.2 mm or more and 1 mm or less, for example. The size of the extension 40B2 of the lens 40B in the Y direction may be 0.2 mm or more and 3 mm or less, for example, and the size in the Z direction may be 0.05 mm or more and 0.8 mm or less, for example.

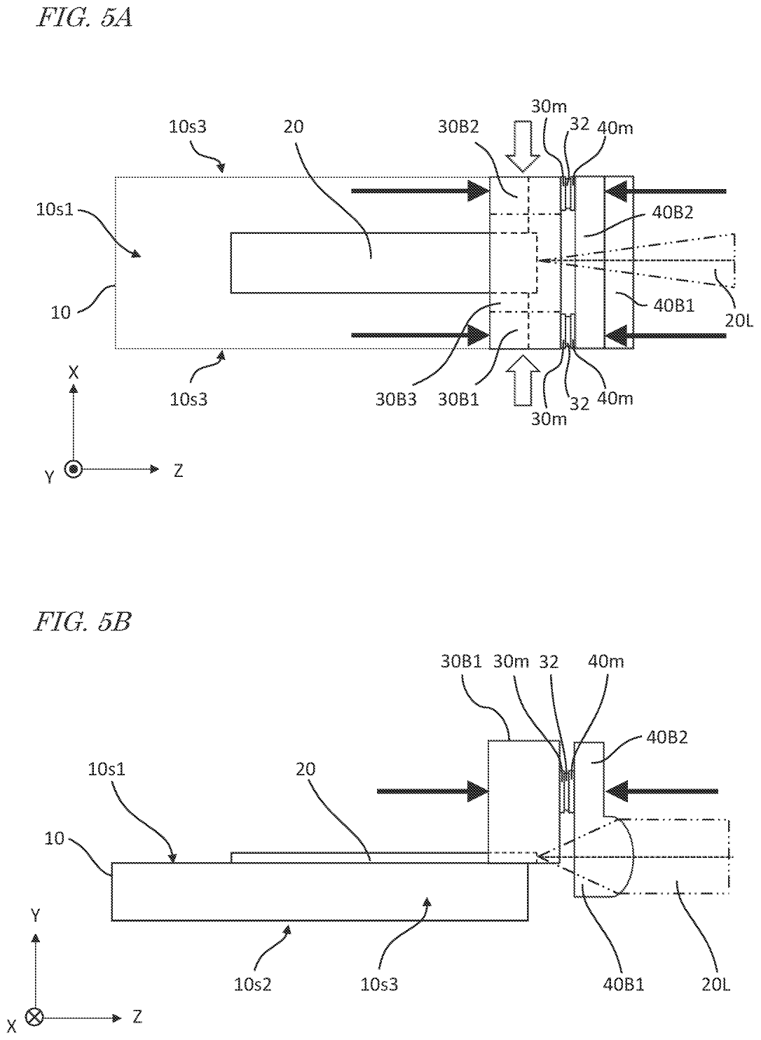

Next, referring to FIG. 5A and FIG. 5B, an example of a method for bonding the support member 30B and the lens 40B will be described. Before heating the bonding member 32, the support member 30B and the lens 40B are connected together with the bonding member 32 interposed therebetween. In this connection process, the surfaces of the first portion 30B1 of the support member 30B and the extension 40B2 of the lens 40B facing each other are generally parallel to each other. Similarly, the surfaces of the second portion 30B2 of the support member 30B and the extension 40B2 of the lens 40B facing each other are generally parallel to each other. The angle formed by these surfaces may be 0° or more and 10° or less, for example.

FIG. 5A and FIG. 5B are views illustrating a method for bonding together the support member 30B and the lens 40B in Embodiment 2. The area surrounded by the two-dot-chain line shown in FIG. 5A and FIG. 5B represent the primary part of a laser beam 20L emitted from the semiconductor laser element 20.

As shown in FIG. 5A, the heating laser beam is emitted toward the lateral surfaces of the first portion 30B1 and the second portion 30B2. The details of the heating laser beam are as described in Embodiment 1. As shown in FIG. 4E, the light-incident surface (the broken-line ellipse) of the lens 40B, on which the laser beam emitted from the semiconductor laser element 20 is incident, is sufficiently away from the bonding member 32 disposed on the first portion 30B1 and the second portion 30B2. Therefore, even if the bonding member 32 bumps while being heated, it is possible to reduce the possibility for a part of the bumping bonding member 32 to splash to the light-incident surface of the lens 40B. The shortest distance in the XY plane between the light-incident surface of the lens 40B and the bonding member 32 may be 0.2 mm or more and 1 mm or less, for example. With the laser light source 100B according to Embodiment 2, it is possible to suppress the burning of the lens 40B. With the laser light source 100B according to Embodiment 2, the laser beam can be efficiently extracted to the outside.

While heating the bonding member 32, the first portion 30B1 and the second portion 30B2 and the extension 40B2 are pressed against each other from opposite directions along one axis that is parallel to the optical axis of the laser beam (the dotted line). This pressing is performed as represented by bold arrows shown in FIG. 5A and FIG. 5B. Because the first portion 30B1 and the second portion 30B2 and the lens 40B are pressed against each other along one axis, it is possible to suppress misalignment of the lens 40B while being pressed. As shown in FIG. 4C and FIG. 4D, the surfaces of the first portion 30B1 and the second portion 30B2 that face the surface on which the extension 40B2 is provided are located away from the upper surface 10s1 of the submount 10. Therefore, it is possible to prevent the submount 10 from interfering with the pressing. As shown in FIG. 5A and FIG. 5B, the lens 40B can be pressed while the laser beam 20L is emitted from the semiconductor laser element 20. The bonding member 32 formed from a metal paste is flexible, thereby facilitating the alignment of the lens 40B, as described above in Embodiment 1.

The method for manufacturing a semiconductor device of the present disclosure is applicable to laser light sources used in various applications, such as machining, projectors, displays and lighting appliances, for example.

What is claimed is:

1. A laser light source comprising:
a submount having an upper surface;
a semiconductor laser element located on the upper surface of the submount and having an end surface from which a laser beam is emitted;
a lens facing the end surface of the semiconductor laser element; and
a support member located on the upper surface of the submount and supporting the lens; wherein:
the lens comprises a collimating portion configured to collimate the laser beam emitted from the semiconductor laser element;
the support member comprises:
a first portion and a second portion arranged at a lateral side of the submount; and
a third portion that connects the first portion and the second portion and overlaps a portion of the semiconductor laser element in a plan view; and
the lens is supported by the first portion and the second portion of the support member via a bonding member interposed between the lens and each of the first portion and the second portion.

2. The laser light source according to claim 1, wherein:
the submount has a lower surface on a side opposite to the upper surface; and
each of the first portion and the second portion has a bottom surface, and the bottom surface of each of the first portion and the second portion is located below a plane of the upper surface of the submount and above a plane of the lower surface of the submount.

3. The laser light source according to claim 2, wherein the bottom surface of each of the first portion and the second portion is located below a plane that includes an optical axis of the lens and is parallel to the bottom surface.

4. The laser light source according to claim 1, wherein:
the third portion is bonded to the upper surface of the submount; and
the first portion and the second portion are not bonded to the submount.

5. The laser light source according to claim 1, wherein a gap is located between the first portion and the submount, and a gap is located between the second portion and the submount.

6. The laser light source according to claim 4, wherein a gap is located between the first portion and the submount, and a gap is located between the second portion and the submount.

7. The laser light source according to claim 1, wherein a size of the first portion and a size of the second portion are greater than a size of the lens in a direction normal to the upper surface of the submount.

8. A laser light source comprising:
a submount having an upper surface;
a semiconductor laser element located on the upper surface of the submount and having an end surface from which a laser beam is emitted;
a lens facing the end surface of the semiconductor laser element; and
a support member located on the upper surface of the submount and supporting the lens, wherein:
the lens comprises:
a collimating portion that faces the end surface of the semiconductor laser element and is configured to collimate the laser beam emitted from the semiconductor laser element; and
an extension that extends from the collimating portion in a direction that is parallel to the end surface of the semiconductor laser element; and
the lens is supported via a bonding member disposed at least between the extension and the support member.

9. The laser light source according to claim 8, wherein the extension extends in a direction normal to the upper surface of the submount.

10. The laser light source according to claim 9, wherein the bonding member is disposed only at positions such that the bonding member is not irradiated with the laser beam emitted from the semiconductor laser element when the semiconductor laser element is driven.

11. The laser light source according to claim 8, wherein the collimating portion and the extension are monolithic.

12. The laser light source according to claim 1, wherein:
the submount has a front surface on a side where the lens is located; and
bonding surfaces of the first portion and the second portion on which the bonding member is disposed are located on a plane of the front surface or on a lens side of the plane of the front surface.

13. The laser light source according to claim 6, wherein:
the submount has a front surface on a side where the lens is located; and
bonding surfaces of the first portion and the second portion on which the bonding member is disposed are located on a plane of the front surface or on a lens side of the plane of the front surface.

14. The laser light source according to claim 1, wherein the first portion, the second portion and the third portion are monolithic.

15. The laser light source according to claim 6, wherein the first portion, the second portion and the third portion are monolithic.

16. The laser light source according to claim 1, wherein a thermal conductivity of a material of the support member is higher than a thermal conductivity of a material of the lens and less than or equal to a thermal conductivity of a material of the submount.

17. The laser light source according to claim 1, wherein the collimating portion is configured to collimate a fast axis direction of the laser beam.

18. The laser light source according to claim 8, wherein the collimating portion is configured to collimate a fast axis direction of the laser beam.
